(19) United States
(12) Patent Application Publication
(10) Pub. No.: US 2023/0232598 A1
(43) Pub. Date: Jul. 20, 2023

(54) POWER SUPPLY UNIT, LIQUID COOLED ENCLOSURE AND METHOD THEREOF

(71) Applicant: Lite-On Singapore Pte Ltd, Singapore (SG)

(72) Inventors: Peng GAO, Singapore (SG); Neilson NG, Singapore (SG); Karthikeyan Kumarasamy, Singapore (SG)

(73) Assignee: Lite-On Singapore Pte Ltd, Singapore (SG)

(21) Appl. No.: 17/726,520

(22) Filed: Apr. 21, 2022

Related U.S. Application Data
(60) Provisional application No. 63/299,413, filed on Jan. 14, 2022.

(51) Int. Cl. H05K 7/20

(52) U.S. Cl. CPC H05K 7/20927; H05K 7/209; H05K 7/20263

(57) ABSTRACT

A liquid cooled enclosure for transfer heat from a printed circuit board assembly (PCBA) which is disposed inside the liquid cooled enclosure is introduced. The liquid cooled enclosure includes a first cover structure, a cooler structure and a second cover structure. The cooler structure, which is mounted on the first cover structure, includes a hollow tube with a predefined shape pattern. The second cover structure includes an elastic pad that is disposed on a surface of the second cover structure. The PCBA is floatingly mounted on the elastic pad of the second cover structure, and the elastic pad is configured to push the PCBA toward the cooler structure such that heat from the PCBA is dissipated via the cooler structure.

### CROSS REFERENCE TO RELATED APPLICATION

This application claims the priority benefit of U.S. Provisional Application Serial No. 63/299,413, filed on Jan. 14, 2022. The entirety of the above-mentioned patent application is hereby incorporated by reference herein and made a part of this specification.

### BACKGROUND

### Technical Field

The disclosure relates to thermal cooling, and more particularly to a liquid cooled enclosure, a power supply unit including a liquid cooled enclosure and a printed circuit board assembly, and a method thereof.

### Description of Related Art

An electronic device with high-powered electronic components such as a power supply unit generates heat during its operation, resulting in low performance and low efficiency of the electronic device. A cooling system is commonly used to dissipate the heat from the electronic device, thereby improving the efficiency of the electronic device. It has been known that liquid cooling provides more efficient cooling compared to traditionally used air cooling. However, the existing liquid cooling systems are bulky, space-occupied, and are not suitable for a compact enclosure with high-powered electronic components built-in. In addition, the existing cooling systems are complex to assemble or disassemble, resulting in a poor serviceability.

As strong demand for miniaturization of high-powered electronics, it is desirable for a novel design of cooling system that is highly efficient, compact and easy to assemble or disassemble for serviceability. Nothing herein should be construed as an admission of knowledge in the prior art of any portion of the present disclosure.

### SUMMARY

The disclosure introduces a power supply unit, a method and a liquid cooled enclosure with efficient cooling solution enabling compactness and easy to assemble disassemble for serviceability.

In some embodiments, the power supply unit includes a liquid cooled enclosure and a printed circuit board assembly of a power supply unit that is disposed inside the liquid cooled enclosure. The liquid cooled enclosure is configured to transfer heat from the printed circuit board assembly of the power supply unit. The liquid cooled enclosure includes a first cover structure, a cooler structure and a second cover structure. The cooler structure, which is mounted on the first cover structure, includes a hollow tube with a predefined shape pattern. The second cover structure includes an elastic pad that is disposed on a surface of the second cover structure. The printed circuit board assembly is floatingly mounted on the elastic pad of the second cover structure, and the elastic pad is configured to push the printed circuit board assembly toward the cooler structure such that heat from the printed circuit board assembly is transferred to the first cover structure via the cooler structure.

In some embodiments, the liquid cooled enclosure is configured to transfer heat from a printed circuit board assembly which is disposed inside the liquid cooled enclosure. The liquid cooled enclosure includes a first cover structure, a cooler structure and a second cover structure. The cooler structure, which is mounted on the first cover structure, includes a hollow tube with a predefined shape pattern. The second cover structure includes an elastic pad that is disposed on a surface of the second cover structure. The printed circuit board assembly is floatingly mounted on the elastic pad of the second cover structure, and the elastic pad is configured to push the printed circuit board assembly toward the cooler structure such that heat from the printed circuit board assembly is transferred to the first cover structure via the cooler structure.

In some embodiments, a method of fabricating a cooler structure of a liquid cooled enclosure, wherein the liquid cooled enclosure includes a first cover structure, the cooler structure and a second cover structure, the cooler structure which comprises a hollow tube with a predefined shape, the cooler structure is mounted on the first cover structure, the second cooler structure comprises an elastic pad that is disposed on a surface of the second cover structure, and the liquid cooled enclosure is configured to transfer heat from a printed circuit board assembly which is disposed inside the liquid cooled enclosure. The method includes steps of performing a bending process to form the predefined shape pattern of the hollow tube; performing a pressing process to change a cross-section shape of the hollow tube, wherein the hollow tube comprises a flat surface and the cross-section shape of the hollow tube is an oval shape after the pressing process is performed; performing a brazing process to connect a first terminal of the hollow tube and a second terminal of the hollow tube to a first connector and a second connector, respectively; and performing a surface treatment process to form an anti-oxidation layer on the hollow tube.

According to embodiments of the disclosure, the cooler structure is mounted on the first cover structure of the liquid cooled enclosure, in which the cooler structure has a flat tube structure with a predefined shape pattern. In this way, the cooling efficiency of the liquid cooled enclosure is improved and a slim liquid cooled enclosure is achievable. In addition, the printed circuit board assembly is floatingly mounted on the second cover structure via stand-offs and elastic pads that are disposed on a surface of the second cover structure. An internal force generated by the elastic pad pushes the printed circuit board assembly upward to form a tight contact between the printed circuit board assembly and the cooler structure. As such, the cooling efficiency of the liquid cooled enclosure is further improved. Furthermore, the liquid cooled enclosure may further include a heat sink that is sandwiched between the printed circuit board assembly and the cooler structure to further improving cooling efficiency of the liquid cooled enclosure.

### BRIEF DESCRIPTION OF THE DRAWINGS

FIG. 1 is a schematic diagram of a power supply unit including a printed circuit board assembly and a liquid cooled enclosure in accordance with some embodiments.

FIG. 2A is a schematic diagram of a first cover structure and a cooler structure of a liquid cooled enclosure in accordance with some embodiments.

FIG. 2B is a cross-sectional view of a cooler structure in accordance with some embodiments.

FIG. 3A and FIG. 3B are cross-sectional views of a printed circuit board assembly and a liquid cooled enclosure in accordance with some embodiments.

FIG. 4A to FIG. 4C illustrate a process of assembling or disassembling a power supply unit including a printed circuit board assembly and a liquid cooled enclosure in accordance with some embodiments.

FIG. 5 is a flowchart diagram of a method for fabricating a cooler structure of a liquid cooled enclosure in accordance with some embodiments.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

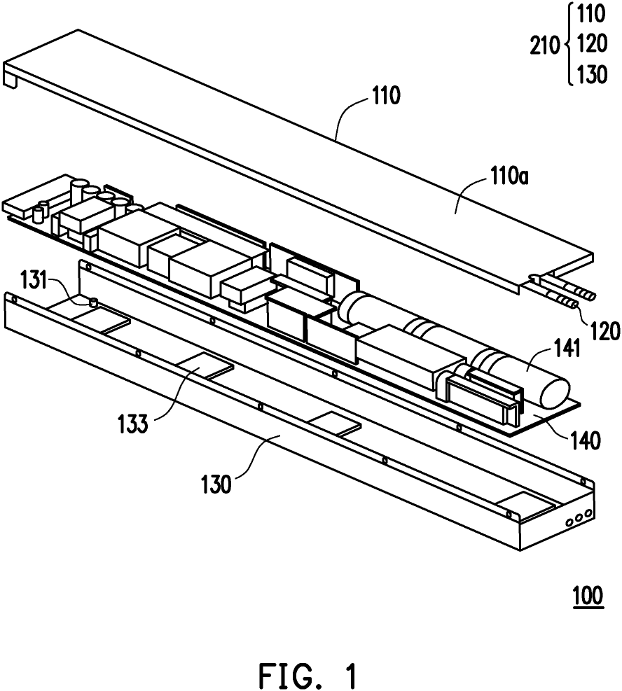

FIG. 1 illustrates a schematic diagram of a power supply unit 100 that includes a printed circuit board assembly (PCBA) 140 and a liquid cooled enclosure 210 in accordance with some embodiments. The PCBA 140 is disposed inside the liquid cooled enclosure 210. The PCBA 140 may include a printed circuit board and a plurality of electronic components 141 such as resistors, transistors, inductors, transformers, or other electronic components. In some embodiments, the electronic components 141 of the PCBA 140 include at least one active electronic component such as a metal-oxide-semiconductor field-effect transistor (MOSFET) and/or at least one passive electronic component such as a transformer and a choke inductor. The PCBA 140 may be a power supply unit that is configured to supply power to external electronic devices (not shown). The PCBA 140 may have functions of converting alternating current (AC) power to direct current (DC) power and transferring the DC power to the external electronic devices. The PCBA 140 may further include a circuitry for improving the efficiency of the power supply unit. For example, the PCBA 140 may include a switching regulator to convert electrical power efficiently. It is appreciated that the disclosure does not intend to limit the PCBA 140 to any particular circuit or electronic device, and any heat-generating electronic device falls within the scope of the disclosure.

The liquid cooled enclosure 210 may include a first cover structure 110 (also referred to as a top cover structure), a cooler structure 120 and a second cover structure 130 (also referred to as a bottom cover structure). The first cover structure 110 may have an outer surface 110a and an inner surface 110b, in which the inner surface 110b may contact the cooler structure 120. The first cover structure 110 of the liquid cooled enclosure 210 may be made of material with high thermal conductivity such as metal, and the first cover structure 110 may have a U-shape in a cross-sectional view. In an example, the first cover structure 110 is formed by a sheet metal forming, in which a piece of metal sheet is modified to form a desired shaped structure. A material of the first cover structure 110 may include a carbon steel with zinc plated, such as a cold rolled steel sheet (SPCC), a cold rolled hot dip galvanized steel sheet (SGCC) or galvanized steel sheet (SECC). The disclosure does not intend to limit the method of forming the first cover structure to sheet metal forming. Any other suitable technique may be used to fabricate the first cover structure 110.

In some embodiments, the cooler structure 120 includes a first surface and a second surface, in which the first surface of the cooler structure 120 is mounted to the inner surface 110b of the first cover structure 110, and a second surface of the cooler structure 120 may contact at least one electronic component of the PCBA 140. The cooler structure 120 may directly contact the inner surface 110b of the first cover structure 110 and the electronic component of the PCBA 140. Alternatively, the cooler structure 120 may indirectly contact the inner surface 110b of the first cover structure 110 and the electronic component of the PCBA 140 via thermal interface layers such as thermal paste layers or thin thermal sheets (not shown). The cooler structure 120 is configured to transfer heat from the electronic components of the PCBA 140 to the internal flowing liquid (e.g., water). The heat is then dissipated to surrounding environment through an external heat exchanger (not shown).

The cooler structure 120 may be made from metal or any suitable material that is capable of conducting and transferring heat. In some embodiments, the cooler structure 120 is made from a single material having high thermal conductivity, such as copper. The usage of single material having high thermal conductivity for the cooler structure 120 may improve the cooling efficiency and simplify the fabrication process of the cooler structure 120. Accordingly, the liquid cooled enclosure 210 with high cooling efficiency and slim profile is achievable.

In some embodiments, the second cover structure 130 includes at least one stand-off 131 and at least one elastic pad 133 allocated on a surface (i.e., inner surface) of the second cover structure 130. The stand-off 131 is configured to align the PCBA 140 with a predefined position after the PCBA 140 is assembled to the liquid cooled enclosure 210. In other words, the stand-off 131 is configured to fix the position of the PCBA 140 after the PCBA 140 is assembled to the liquid cooled enclosure 210. The elastic pad 133 is distributed to at least one predefined location on the second cover structure 130 and is configured to support the PCBA 140. In some embodiments, the PCBA 140 is floatingly mounted without a screw, and the PCBA 140 is sandwiched in between the first cover structure 110 and the second cover structure 130. When the first cover structure 110 is assembled with the second cover structure 130 to form the liquid cooled enclosure 210, an internal force will be produced locally due to elastic deformation of elastic pad 133. The internal force that is produced by the elastic pad 133 pushes the PCBA 140 toward the cooler structure 120 to tightly contact the PCBA 140 with the cooler structure 120, resulting in improved thermal conduction between the PCBA 140 and cooler structure 120. In some embodiments, the second cover structure 130 have a U-shape in a cross-sectional view. The U-shape of the second cover structure 130 may be deeper than the U-shape of the first cover structure 110 in some embodiments. The first cover structure 110 may be assembled with the second cover structure 130 using at least one screw (not shown), but the disclosure is not limited to any particular technique or means to assemble the first cover structure 110 and the second cover structure 130 of the liquid cooled enclosure 210.

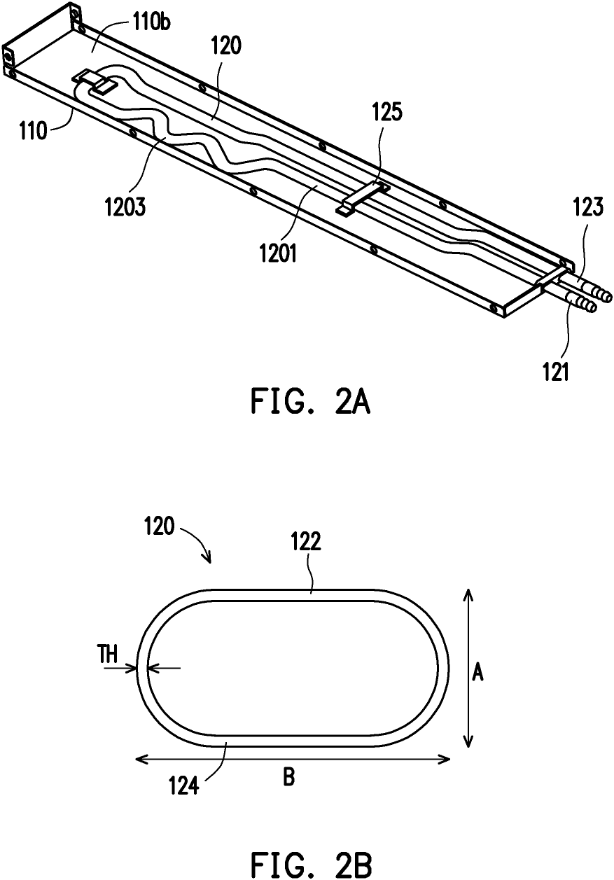

FIG. 2A illustrates a schematic diagram of the first cover structure 110 and the cooler structure 120 of the liquid cooled enclosure 210 in accordance with some embodiments. The first cover structure 110 in FIG. 2A is the same as the first cover structure 110 in FIG. 1, thus the detailed description of the first cover structure 110 in FIG. 2A is omitted hereafter. As shown in FIG. 2A, the cooler structure 120 is fastened to an inner surface 110b of the first cover structure 110 by at least one mounting bracket 125. The inner surface 110b of the first cover structure 110 is a surface that faces the PCBA 140 when the liquid cooled enclosure 210 is assembled. The mounting bracket 125 is configured to fix the position of the cooler structure 120 on the first cover structure 110 and to form a tight thermal conduction between the cooler structure 120 and the first cover structure 110. The cooler structure 120 may directly contact the first cover structure 110 or may indirectly contact the first cover structure 110 via a thermal interface layer (i.e., thermal paste or a thin metal layer). The mounting bracket 125 may be made from metal, but the disclosure is not limited thereto. It is appreciated that the material of the mounting bracket 125, a number of the mounting bracket 125 and a size and shape of the mounting bracket 125 are determined according to the desired requirements.

The cooler structure 120 may further include an inlet port 121 and an outlet port 123, in which heat-transfer fluid enters the cooler structure 120 via the inlet port 121 and the heat-transfer fluid exits the cooler structure 120 via the outlet port 123. The cooler structure 120 allows the heat-transfer liquid to flow in and out for heat removal of heat-generating electronic components in PCBA 140 via thermal conduction. The heat-transfer fluid may be water or any other suitable fluid for heat transferring.

The cooler structure 120 may have a predefined shape pattern that includes at least one straight portion 1201 and at least one curved portion 1203 (i.e., a pre-bend curvature). A number of the straight portions and curved portions of the cooler structure 120 may change a heat absorption rate and a heat transferring rate of the cooler structure 120. For example, a cooler structure 120 with a large number of curved portions may allow more effectively to absorb and transfer large amounts of heat. Thus, the predefined shape pattern and the numbers of straight and curved portions of the cooler structure 120 may be selected differently based on the designed requirements.

In some embodiments, the cooler structure 120 may have a tubular shape (i.e., a hollow tube) with a thin wall. FIG. 2B illustrates a cross-sectional view of a hollow tube of the cooler structure 120 in accordance with some embodiments. In cross-sectional view, the hollow tube of the cooler structure 120 has a length B, a width A and a wall thickness TH, in which the length B, the width A, and the wall thickness TH of the hollow tube may be determined according to the desired requirement. In some embodiments, the wall thickness TH of the hollow tube is in a range from 0.5 mm to 1 mm.

In some embodiments, the cooler structure 120 has a flat tube structure. For example, the cooler structure 120 may include a first surface 122 and a second surface 124, in which the first surface 122 and the second surface 124 are flat surfaces. In this way, effective contacts are formed among the surfaces 122, 124 of the cooler structure 120, the first cover structure 110 and the electronic components in the PCBA 140, resulting in improved cooling efficiency of the liquid cooled enclosure 210. In some embodiments, a first terminal of the hollow tube is connected to a first connector to form the inlet port 121 of the cooler structure 120, and a second terminal of the hollow tube is connected to a second connector to form the outlet port 123 of the cooler structure 120. In some embodiments, the hollow tube of the cooler structure 120 has an oval cross-sectional shape, but the disclosure is not limited thereto. The cross-sectional shape, the material and the wall thickness of the cooler structure 120 may be modified according to designed requirements.

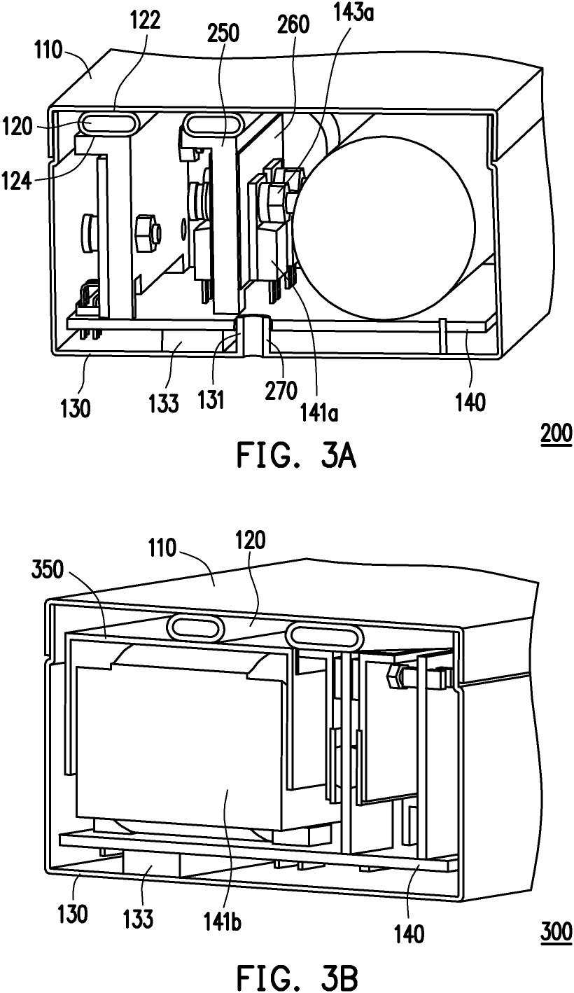

FIG. 3A is a cross-sectional view of a power supply unit 200 that includes a PCBA 140 and a liquid cooled enclosure in accordance with some embodiments. The same elements of the power supply unit 200 in FIG. 3A and the power supply unit 100 in FIG. 1 are illustrated by same reference numbers. A difference between the power supply unit 200 in FIG. 3A and the power supply unit 100 in FIG. 1 is that the power supply unit 200 further includes a heat sink 250 where an active electric component 141a of the PCBA 140 is mounted on. The active electric component 141a may be a transistor or any other types of active electric components of the PCBA 140. The active electric component 141a may be mounted on the heat sink 250 by a screw 143a, but the disclosure is not limited to thereto. It is appreciated that any other fastening means that are capable of mounting the active electric component 141a to the heat sink 250 falls within the scope of the disclosure. In some embodiments, the heat sink 250 is an L-shaped heat sink, in which a surface of the heat sink 250 contacts the cooler structure 120 and another surface of the heat sink 250 is mounted onto the active electric component 141a. In some embodiments, a layer of thermal paste or thermal sheet (not shown) is disposed between the cooler structure 120 and the heat sink 250 to improve the cooling efficiency of the power supply unit 200. The heat sink 250 serves as a heat transfer path that transfers heat from the active electric component 141a to the cooler structure 120.

In some embodiments, the power supply unit 200 may further include a thermal interface layer 260 that is sandwiched between the active electric component 141a and the heat sink 250. The thermal interface layer 260 is configured to improve the heat transfer efficiency between the active electric component 141a and the heat sink 250. In some embodiments, the thermal interface layer 260 is a thin sheet with a thickness in a range from 0.1 mm to 0.5 mm and a conductivity in a range from 2 W/mK to 5 W/mK, in which W/mK stands for watts per meter-Kelvin. The active electric component 141a, the thermal interface layer 260 and the heat sink 250 may be fastened together using the screw 143a. In some embodiments, the power supply unit 200 may further include a through-hole 270 on the surface of the second cover structure 130, in which the through-hole 270 and the stand-off 131 are configured to fix the position of the PCBA 140 when the PCBA 140 is assembled to the liquid cooled enclosure. As shown in FIG. 3A, the elastic pad 133 of the second cover structure 130 is configured to push the PCBA 140 toward the cooler structure 120 when the power supply unit 200 is assembled. In this way, thermal conduction of the PCBA 140, the heat sink 250 and the cooler structure 120 is improved, and highly efficient cooling effect is achieved.

FIG. 3B is a cross-sectional view of a power supply unit 300 that includes a PCBA 140 and a liquid cooled enclosure in accordance with some embodiments. The same elements of the power supply unit 300 in FIG. 3B and the power supply unit 100 in FIG. 1 are illustrated by same reference numbers. A difference between the power supply unit 300 in FIG. 3B and the power supply unit 100 in FIG. 1 is that the power supply unit 300 further includes a heat sink 350 where a passive electric component 141b of the PCBA 140 is mounted on. The passive electric component 141b may be a transformer or a choke inductor or any other passive electric components of the PCBA 140. In some embodiments, the heat sink 350 is configured to cover a portion of the passive electric component 141b or the entire passive electric component 141b for absorbing heat from the passive electric component 141b. The heat sink 350 may be a U-shaped heat sink in cross-sectional view, but the disclosure is not limited thereto. The shape of the heat sink 350 may be determined according to the designed requirements. In some embodiments, the power supply unit 300 further includes a thermal interface layer (not shown) that is disposed between the heat sink 350 and the passive electric component 141b to improve the thermal conduction between the heat sink 350 and the passive electric component 141b. The thermal interface layer between the heat sink 350 and the passive electric component 141b may be a potting compound having a conductivity in a range from 1.5 W/mK to 3.5 W/mK.

In some embodiments, the heat sink 350 directly contacts the cooler structure 120 and the heat sink 350 to transfer heat from the passive electric component 141b to the heat sink 350. In some embodiments, a thermal paste layer (not shown) is disposed between the heat sink 350 and the cooler structure 120 to improve the thermal conduction between the heat sink 350 and the cooler structure 120. In some embodiments, a dielectric thermal sheet with a thickness in a range from 0.1 mm to 0.3 mm is sandwiched between the heat sink 350 and the cooler structure 120 to improve the thermal conduction while electrically insulating the heat sink 350 from the cooler structure 120. As shown in FIG. 3B, the elastic pad 133 of the second cover structure 130 is configured to push the PCBA 140 toward the cooler structure 120 when the power supply unit 300 is assembled. In this way, thermal conduction of the PCBA 140, the heat sink 350 and the cooler structure 120 is improved, and highly efficient cooling effect is achieved.

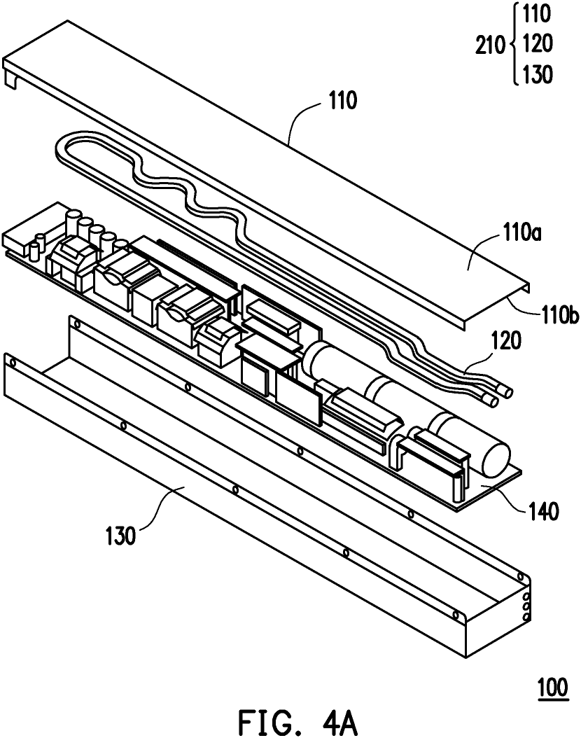

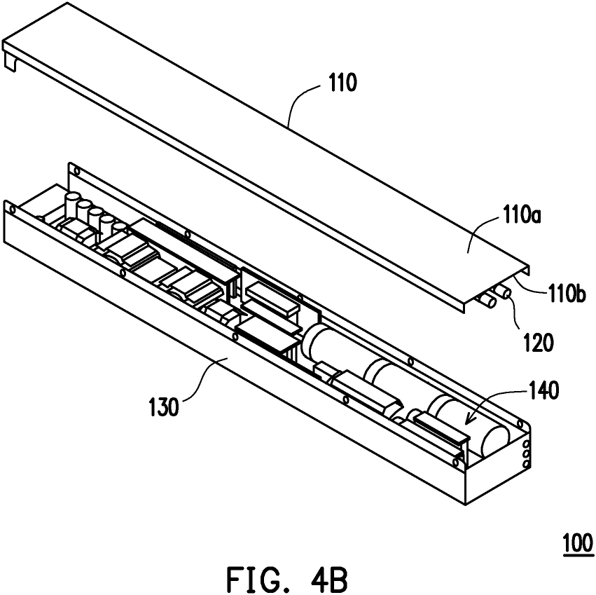

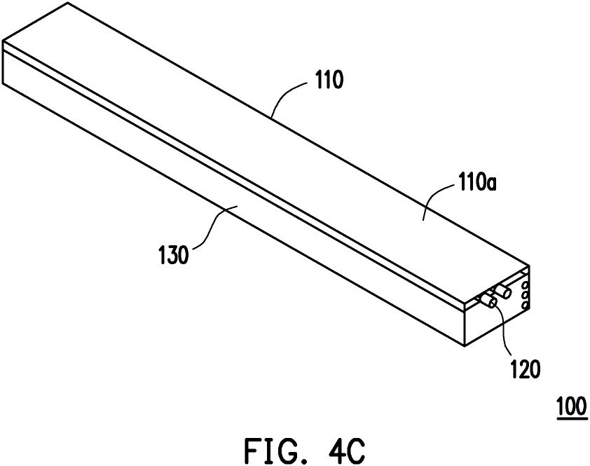

FIG. 4A to FIG. 4C illustrate a process of assembling or disassembling the power supply unit 100 including the PCBA 140 and the liquid cooled enclosure 210 in accordance with some embodiments. The liquid cooled enclosure 210 includes the first cover structure 110, the cooler structure 120 and the second cover structure 130. An assembly of the power supply unit 100 may start from the process illustrated in FIG. 4A and ends at the process illustrated in FIG. 4C. Referring to FIG. 4A and FIG. 4B, the cooler structure 120 is combined with the first cover structure 110 to form a first sub-assembly (also referred to as a cooling sub-assembly). In addition, the PCBA 140 is combined with the second cover structure 120 to form a second sub-assembly (also referred to as an electronic sub-assembly). Referring to FIG. 4C, the first sub-assembly is fixed to the second sub-assembly by side screws or any other fastening means to form a full assembly of the power supply unit 100.

A disassembly of the power supply unit 100 may start from the process illustrated in FIG. 4C and ends at the process illustrated in FIG. 4A. For example, the full assembly of the power supply unit 100 in FIG. 4C may be disassembled to the first and second sub-assemblies as illustrated in FIG. 4B. Each of the first and second sub-assemblies can be maintained and/or repaired separately. In addition, the first sub-assembly may be disassembled to separate the cooler structure 120 and the first cover structure 110; and the second sub-assembly may be disassembled to separate the PCBA 140 and the second cover structure 130. In this way, the process of assembling or disassembling the power supply unit 100 is simplified, and the serviceability of the assembly of the power supply unit 100 is improved.

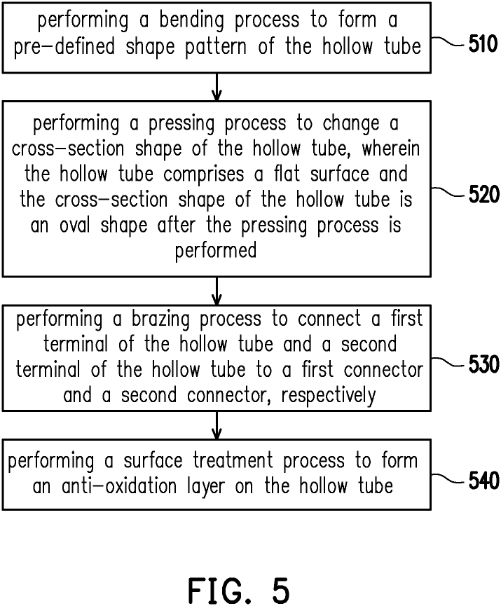

FIG. 5 is a flowchart diagram of a method for fabricating a cooler structure (i.e., color structure 120 in FIG. 1) in accordance with some embodiments. In step 510, a bending process is performed on a hollow tube to form a predefined shape pattern of the hollow tube. In some embodiment, the predefined shape pattern includes at least one straight portion and/or at least one curved portion (i.e., pre-bend curvature). In some embodiment, all curved portions have the same bending radius. In step 520, a pressing process is performed to change a cross-section shape of the hollow tube, wherein the hollow tube comprises a flat surface and the cross-section shape of the hollow tube is an oval shape after the pressing process is performed. Such a cross-section shape of the hollow tube is beneficial for effective contact with the first cover structure and the PCBA. In step 530, a brazing process is performed to connect a first terminal of the hollow tube and a second terminal of the hollow tube to a first connector and a second connector, respectively. The brazing process may form an inlet port and an outlet port of the cooler structure. In step 540, a surface treatment process is performed to form an anti-oxidation layer on the hollow tube. In some embodiments, a Ni-plating is applied to the surface of the hollow tube to avoid corrosion and oxidation.

In the embodiments of the disclosure, a cooler structure that has a flat tube structure with a predefined shape pattern is mounted on a surface of a first cover structure of a liquid cooled enclosure, thus a slim and highly cooling efficient liquid cooled enclosure is achieved. In addition, elastic pads of a second cover structure are configured to push the printed circuit board assembly upward to form a tight contact between the printed circuit board assembly and the cooler structure, thereby further improving cooling efficiency of the liquid cooled enclosure. A heat sink and thermal interface layer may be included in the liquid cooled enclosure to further improve cooling efficiency of the liquid cooled enclosure. Furthermore, a process of assembling and disassembling of a power supply unit including the liquid cooled enclosure and the printed circuit board assembly are simplified, resulting in an improved serviceability of the power supply unit. Thus, a compact power supply unit in a highly cooling efficient liquid cooled enclosure is obtained.

Although the embodiment of the disclosure has been described in detail, the disclosure is not limited to a specific embodiment and various modifications and changes are possible within the scope of the disclosure disclosed in the claims.

What is claimed is:

1. A power supply unit, comprising:
a printed circuit board assembly; and
a liquid cooled enclosure, wherein the printed circuit board assembly is disposed inside the liquid cooled enclosure, wherein the liquid cooled enclosure comprises:
a first cover structure;
a cooler structure, mounted on the first cover structure, comprising a hollow tube with a predefined shape pattern; and
a second cover structure, comprising an elastic pad that is disposed on a surface of the second cover structure,
wherein the printed circuit board assembly is floatingly mounted on the elastic pad of the second cover structure, and the elastic pad is configured to push the printed circuit board assembly toward the cooler structure.

2. The power supply unit of claim 1, wherein the cooler structure is mounted on an inner surface of the first cover structure.

3. The power supply unit of claim 2, wherein
the liquid cooled enclosure further comprises a mounting bracket configured to fasten the cooler structure to the inner surface of the first cover structure.

4. The power supply unit of claim 3, wherein the hollow tube has a flat surface, and the flat surface of the hollow tube contacts the first cover structure.

5. The power supply unit of claim 1, wherein the cooler structure comprises:
an inlet port, coupled to a first terminal of the hollow tube; and
an output port, coupled to a second terminal of the hollow tube,
wherein the predefined shape pattern of the hollow tube comprises a straight portion and a curved portion.

6. The power supply unit of claim 1, wherein a wall thickness of the hollow tube is in a range from 0.5 mm to 1 mm.

7. The power supply unit of claim 1, wherein the second cover structure further comprises:
a stand-off, mounted on the surface of the second cover structure, configured to align the printed circuit board assembly with a predetermined position on the second cover structure.

8. The power supply unit of claim 1, further comprising:
a first heat sink, having a L-shape structure and directly contacting the cooler structure,
wherein the printed circuit board assembly comprises an active electronic component that is soldered to the printed circuit board assembly and is mounted on the first heat sink.

9. The power supply unit of claim 8, further comprising:
a first thermal interface layer, disposed between the active electronic component and the first heat sink,
wherein a conductivity of the first thermal interface layer is in a range from 2 W/mK to 5 W/mK.

10. The power supply unit of claim 1, further comprising:
a second heat sink, having a U-shape structure and directly contacting the cooler structure,
wherein the printed circuit board assembly comprises a passive electronic component that is soldered to the printed circuit board assembly and is mounted on the second heat sink.

11. The power supply unit of claim 10, further comprising:
a second thermal interface layer, disposed between the passive electronic component and the second heat sink, wherein
a conductivity of the second thermal interface layer is in a range from 1.5 W/mK to 3.5 W/mK.

12. The power supply unit of claim 1, wherein
a material of each of the first cover structure, the cooler structure and the second cover structure comprises metal, and
each of the first cover structure and the second cover structure has a U-shaped structure.

13. A liquid cooled enclosure comprising:
a first cover structure;
a cooler structure, mounted on the first cover structure, comprising a hollow tube with predefined shape pattern; and
a second cover structure.

14. The liquid cooled enclosure of claim 13, wherein the cooler structure is mounted on an inner surface of the first cover structure.

15. The liquid cooled enclosure of claim 14, further comprising a mounting bracket configured to fasten the cooler structure to the inner surface of the first cover structure.

16. The liquid cooled enclosure of claim 15, wherein the hollow tube of the cooler structure has a flat surface, and the flat surface of the hollow tube contacts the first cover structure.

17. The liquid cooled enclosure of claim 13, wherein the cooler structure comprises:
an inlet port, coupled to a first terminal of the hollow tube; and
an output port, coupled to a second terminal of the hollow tube,
wherein the predefined shape pattern of the hollow tube of the cooler structure comprises a straight portion and a curved portion.

18. The liquid cooled enclosure of claim 13, wherein a wall thickness of the hollow tube of the cooler structure is in a range from 0.5 mm to 1 mm.

19. The liquid cooled enclosure of claim 13, wherein the second cover structure further comprises:
a stand-off, mounted on the surface of the second cover structure.

20. A method of fabricating a cooler structure of a liquid cooled enclosure, wherein the liquid cooled enclosure comprises a first cover structure, the cooler structure and a second cover structure, the cooler structure comprises a hollow tube with a predefined shape pattern, the cooler structure is mounted on the first cover structure, the second cooler structure comprises an elastic pad that is disposed on a surface of the second cover structure, the method comprising:
performing a bending process to form the predefined shape pattern of the hollow tube;
performing a pressing process to change a cross-section shape of the hollow tube, wherein the hollow tube comprises a flat surface and the cross-section shape of the hollow tube is an oval shape after the pressing process is performed;
performing a brazing process to connect a first terminal of the hollow tube and a second terminal of the hollow tube to a first connector and a second connector, respectively.
